(19) United States
(12) Patent Application Publication
(10) Pub. No.: US 2009/0004864 A1
(43) Pub. Date: Jan. 1, 2009

(54) CMP METHOD OF SEMICONDUCTOR DEVICE

(75) Inventors: Tae Kyung Kim, Cheongju-si (KR); Jik Ho Cho, Anyang-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/965,293

(22) Filed: Dec. 27, 2007

(30) Foreign Application Priority Data
Jun. 28, 2007 (KR) 2007-64486

(51) Int. Cl. H01L 21/302

(52) U.S. Cl. 438/693; 257/E21.23

(57) ABSTRACT

The present invention relates to a Chemical Mechanical Polishing (CMP) method of a semiconductor device. According to the method, a metal layer is formed over a semiconductor substrate in which an edge region define. A passivation layer is formed on the metal layer. The passivation layer formed in the edge region is etched in order to expose the metal layer. The exposed metal layer is removed through etching. The metal layer is polished by performing a CMP process, thus forming a metal line.

### CROSS-REFERENCES TO RELATED APPLICATIONS

The present application claims priority to Korean patent application number 10-2007-64486, filed on Jun. 28, 2007, which is incorporated by reference in its entirety.

### BACKGROUND OF THE INVENTION

The present invention relates to a semiconductor device and more particularly to a Chemical Mechanical Polishing (CMP) method, which can remove residue remaining on edge regions of a wafer.

A CMP method is a polishing process in which a chemical reaction by a slurry and a machine processing by a polishing pad are performed at the same time. This CMP method is advantageous in that it can obtain global polishing in comparison with a reflow process, an etch-back process, etc., which were conventionally used for surface planarization, and can also be performed at low temperatures.

In particular, the CMP method was proposed as a polishing process, but has also recently been used as an insulating film etch process for forming an isolation film in a self-aligned contact process and a polysilicon layer etch process for forming a bit line contact plug and a storage node contact plug. Thus, as new uses are found the application field of the CMP method are continuously expanded.

An apparatus used in the CMP method (hereinafter, referred to as a “CMP apparatus”) is described below. The CMP apparatus largely includes a platen having a polishing pad formed thereon, a slurry supply device for supplying a slurry to the polishing pad when a wafer is polished, a polishing head for supporting the wafer on the platen including the polishing pad, and a polishing pad conditioner for reproducing a polishing pad face. However, the conventional CMP method may lead to polishing irregularity within the wafer due to an abrasion characteristic of the polishing pad and a difference in the polishing speed of the wafer depending on the combination between the platen and the pad. Such polishing irregularity is severe at the center and edges of the wafer.

FIG. 1 is a photograph of a device illustrating problems occurring when a conventional CMP process is performed.

When forming a metal line of a semiconductor device employing a damascene process, a tungsten film is formed over a semiconductor substrate and the metal line is formed using a CMP process. At this time, the tungsten film remains irregularly at the edge of the wafer because pad pressure is not constant near the edge of the wafer (i.e., around 10 mm form the edge) where contact between the polishing pad and the wafer stops. If a subsequent thermal process or a subsequent process of depositing or etching an oxide film or a nitride film with great film stress is performed in this state, process abnormalities, such as lifting, particle residues and arching, may occur due to tungsten that remains irregularly.

### BRIEF SUMMARY OF THE INVENTION

The present invention is directed towards a CMP method of a semiconductor device, wherein a metal layer and a passivation layer are sequentially laminated over a semiconductor substrate, the passivation layer in an edge region of the semiconductor substrate is removed using a nozzle for spraying an etchant while rotating the semiconductor substrate, and the metal layer formed in the edge region is removed using an etch-back process, so process abnormalities caused by irregular polishing of the edge region in a subsequent polishing process can be prevented.

A CMP method of a semiconductor device according to an embodiment of the present invention includes forming a metal layer over a semiconductor substrate in which an edge region define, forming a passivation layer on the metal layer, etching the passivation layer formed in the edge region, thus exposing the metal layer, removing the exposed metal layer through etching, and polishing the metal layer by performing a CMP process, thus forming a metal line.

The formation of the metal layer may include forming a hard mask pattern over the semiconductor substrate on which an insulating film is formed, forming a damascene pattern by performing an etch process employing the hard mask pattern, removing the hard mask pattern, and forming the metal layer over a total surface including the damascene pattern.

Before the metal layer is formed, a diffusion prevention layer may be further formed over the entire surface including the damascene pattern. The metal layer may be formed from tungsten, TiSix, TiN, Cu or Al. The diffusion prevention layer may be formed from Ti/TiN or WN.

The edge region of the semiconductor substrate is defined to be 1 to 10 mm.

An etch selectivity of the passivation layer and the metal layer may be in the range of 5:1 to 10:1. The passivation layer may be formed from Spin-On Glass (SOG). The SOG film may be formed using an organic or inorganic type and a slicate, siloxane, silsesquioxane or perhydrosilazane structure.

A bake process and a curing process may be further performed after the passivation layer is formed. The bake process may be performed in a temperature range of 100 to 250 degrees Celsius in N₂ atmosphere. The curing process may be performed in a temperature range of 350 to 450 degrees Celsius in N₂ atmosphere.

The etching of the passivation layer may be performed using an etch process by spraying an etchant on the edge region using a spray nozzle and rotating the semiconductor substrate.

The spray nozzle may spray a SOG solvent to the edge region.

The removal of the metal layer may be performed using an etch process employing SF₆.

The CMP process may be performed using dry fumed SiO₂ or spherical Al₂O₃ having a particle size of 50 to 150 nm at pH 2 to 8.

### BRIEF DESCRIPTION OF THE DRAWINGS

FIG. 1 is a photograph of a device illustrating problems occurring when a conventional CMP process is performed; and

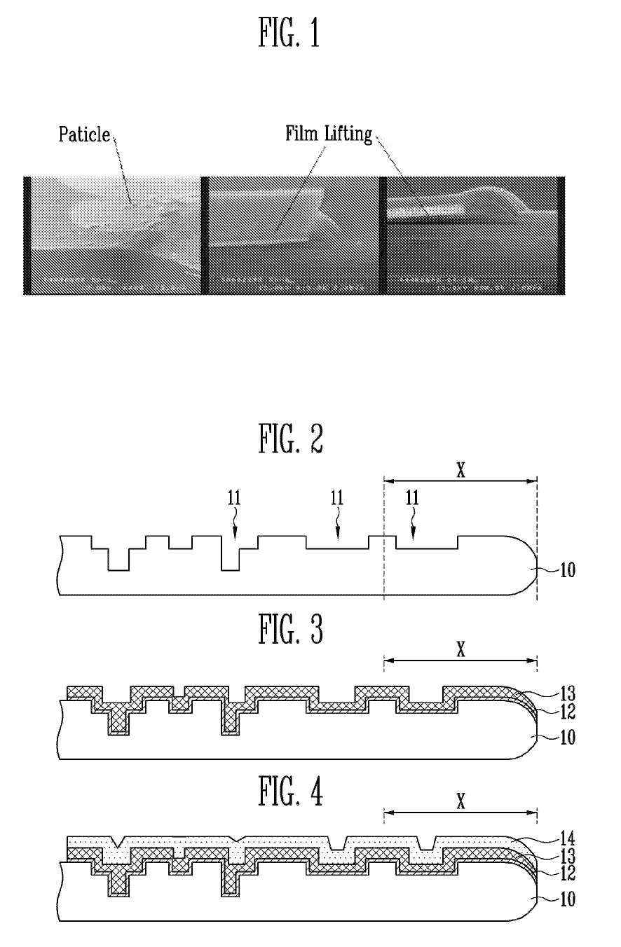

FIGS. 2 to 8 are sectional views illustrating a CMP method of a semiconductor device according to an embodiment of the present invention.

### DESCRIPTION OF SPECIFIC EMBODIMENTS

A specific embodiment according to the present invention will be described with reference to the accompanying drawings.

However, the present invention is not limited to the disclosed embodiment, but may be implemented in various manners. The embodiment is provided to complete the disclosure of the present invention and to allow those having ordinary skill in the art to understand the scope of the present invention. The present invention is defined by the category of the claims.

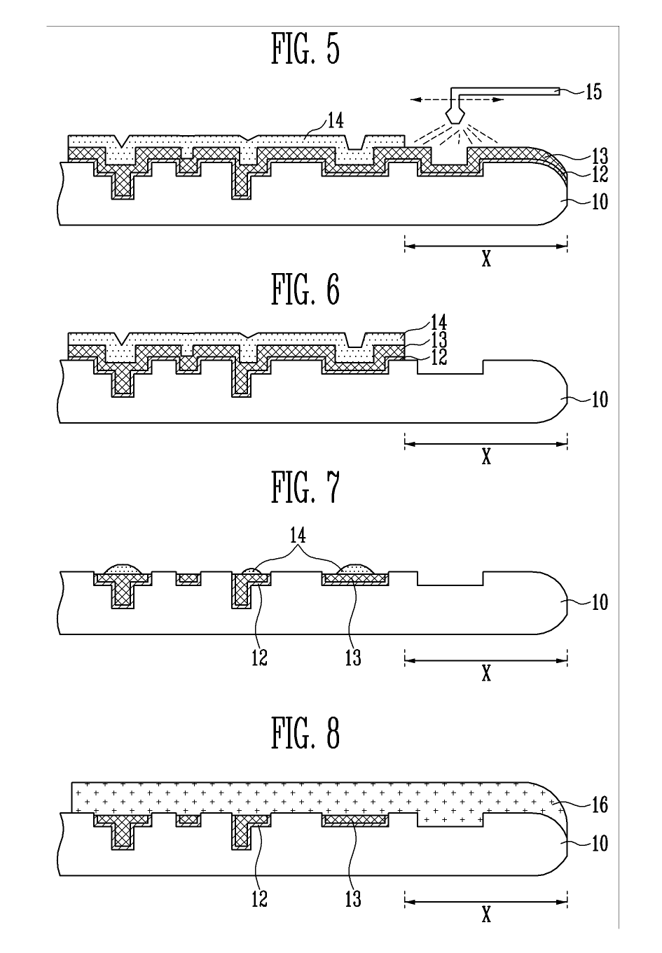

FIGS. 2 to 8 are sectional views illustrating a CMP method of a semiconductor device according to an embodiment of the present invention.

An embodiment of the present invention is described by taking a metal line format method employing a damascene process as an example.

Referring to FIG. 2, a damascene pattern 11 for forming a metal line is formed by etching a semiconductor substrate 10 in which an insulating film is formed. The damascene patterns 11 may be formed by forming hard mask patterns (not shown) on the semiconductor substrate 10 and then performing an etch process using the hard mask pattern as a mask. The hard mask patterns may be formed from silicon nitride or silicon oxide. The hard mask patterns are then removed.

In this case, an edge region X of the semiconductor substrate 10 is defined to be 1 to 10 mm. The edge region X define by considering the arrangement of a die on a wafer, a structure of a process equipment and/or the like.

Referring to FIG. 3, a diffusion prevention layer 12 and a metal layer 13 are sequentially laminated over the entire surface including the damascene patterns. The diffusion prevention layer 12 may be formed from Ti/TiN or WN. The diffusion prevention layer 12 may be formed using a CVD or Physical Vapor Deposition (PVD) method. The metal layer 13 may be formed from tungsten (W). Alternatively, the metal layer 13 may be formed from TiSix, TiN, Cu, Al or the like. The metal layer 13 may be formed to a thickness of 1000 to 5000 angstroms. The metal layer 13 may be formed to fully gap fill the damascene patterns.

Referring to FIG. 4, a passivation layer 14 is formed over the entire surface including the metal layer 13. An etch selectivity of the passivation layer 14 and the metal layer 13 may be in the range of 5:1 to 10:1. The passivation layer 14 may be formed to a thickness of 1000 to 5000 angstroms. The passivation layer 14 may be formed from Spin-On Glass (SOG). The SOG film may be formed using an organic or inorganic type and a slicate, siloxane, silsesquioxane or perhydrosilazane structure.

In order to improve the film quality of the passivation layer 14 (i.e., to remove moisture and a solvent component within the passivation layer 14 and to improve the density), a bake process and a curing process may be performed additionally. The bake process may be performed in a temperature range of 100 to 250 degrees Celsius in N₂ atmosphere. The curing process may be performed in a temperature range of 350 to 450 degrees Celsius in N₂ atmosphere.

Referring to FIG. 5, the passivation layer 14 formed in the edge region X is etched and removed. The etch process may be performed so that a spray nozzle 15 configured to spray an etchant while rotating the semiconductor substrate 10 is positioned over the edge region X of the semiconductor substrate 10. At this time, the spray nozzle 15 is adapted to remove the passivation layer 14 formed in the edge region X by spraying a SOG solvent.

Referring to FIG. 6, the metal layer 13 and the diffusion prevention layer 12 exposed in the edge region X of the semiconductor substrate 10 are etched and removed. The etch process may be performed using SF₆.

Referring to FIG. 7, a metal line 13 is formed by performing a CMP process so that the semiconductor substrate 10 is exposed. The CMP process may be performed using dry fumed SiO₂ or spherical Al₂O₃ having a particle size of 50 to 150 nm at pH 2 to 8.

Referring to FIG. 8, an interlayer insulating film 16 is formed over the entire surface including the metal line 13. The interlayer insulating film 16 may be formed from an oxide film such as BPSG, PSG, FSG, PE-TEOS, PE-SiH₄, HDP USG, HDP PSG or APL. The interlayer insulating film 16 may be formed to a thickness of 2000 to 6000 angstroms.

In accordance with an embodiment of the present invention, the metal layer and the passivation layer are sequentially laminated over the semiconductor substrate, the passivation layer in the edge region of the semiconductor substrate is removed using the nozzle for spraying an etchant while rotating the semiconductor substrate, and the metal layer formed in the edge region is removed using an etch-back process. Accordingly, process abnormalities, such as lifting, particle residues and arching, which are caused by irregular polishing of the edge region in a subsequent polishing process can be prevented.

What is claimed is:

1. A method of making a semiconductor device, the method comprising:
forming a metal layer over a semiconductor substrate in which a edge region define;
forming a passivation layer over the metal layer;
etching the passivation layer formed in the edge region to expose the metal layer;
removing the exposed metal layer; and
polishing the metal layer by performing a chemical mechanical polishing (CMP) process to form a metal line.

2. The method of claim 1, wherein the formation of the metal layer comprises:
forming a hard mask pattern over the semiconductor substrate on which an insulating film is formed;
etching the hard mask pattern to form a damascene pattern; and
removing the hard mask pattern, wherein the metal layer is formed over a resulting surface including the damascene pattern after the hard mask pattern has been removed.

3. The method of claim 2, further comprising forming a diffusion prevention layer over the resulting surface before the metal layer is formed.

4. The method of claim 1, wherein the metal layer is includes tungsten, TiSix, TiN, Cu or Al, or a combination thereof.

5. The method of claim 3, wherein the diffusion prevention layer includes Ti/TiN or WN, or a combination thereof.

6. The method of claim 1, wherein the edge region of the semiconductor substrate is defined to be 1 to 10 mm.

7. The method of claim 1, wherein an etch selectivity of the passivation layer and the metal layer is in the range of 5:1 to 10:1.

8. The method of claim 1, wherein the passivation layer is formed from Spin On Glass (SOG).

9. The method of claim 8, wherein the SOG film is formed using an organic or inorganic type and a slicate, siloxane, silsesquioxane or perhydrosilazane structure.

10. The method of claim 1, further comprising performing a bake process and a curing process after the passivation layer is formed.

11. The method of claim 10, wherein the bake process is performed in a temperature range of 100 to 250 degrees Celsius in N₂ atmosphere.

12. The method of claim 10, wherein the curing process is performed in a temperature range of 350 to 450 degrees Celsius in N₂ atmosphere.

13. The method of claim 1, wherein the etching of the passivation layer is performed using an etch process by spraying an etchant on the edge region using a spray nozzle and rotating the semiconductor substrate.

14. The method of claim 13, wherein the spray nozzle sprays a SOG solvent to the edge region.

15. The method of claim 1, wherein the removal of the metal layer is performed using an etch process employing SF₆.

15. The method of claim 1, wherein the CMP process is performed using dry fumed SiO₂ or spherical Al₂O₃ having a particle size of 50 to 150 nm at pH 2 to 8.
